(19) United States
(12) Patent Application Publication
(10) Pub. No.: US 2025/0014951 A1
(43) Pub. Date: Jan. 9, 2025

(54) SEMICONDUCTOR MODULE AND SEMICONDUCTOR DEVICE

(71) Applicant: FUJI ELECTRIC CO., LTD., Kawasaki-shi (JP)

(72) Inventor: Ryusuke KATO, Matsumoto-shi (JP)

(73) Assignee: FUJI ELECTRIC CO., LTD., Kawasaki-shi (JP)

(21) Appl. No.: 18/679,825

(22) Filed: May 31, 2024

(30) Foreign Application Priority Data
Jul. 5, 2023 (JP) 2023-110560

(51) Int. Cl. H01L 23/049; H01L 23/00

(52) U.S. Cl. CPC H01L 23/049; H01L 24/48; H01L 2224/4846; H01L 2924/13055

(57) ABSTRACT

A semiconductor module includes: a semiconductor element; a conductor pattern including a terminal contact portion electrically connected to the semiconductor element; a sealing body provided to seal the semiconductor element and including an upper surface from which the terminal contact portion is exposed; a case provided with an accommodating portion configured to accommodate the sealing body; and an elastic member that, when an external terminal is inserted, applies a pressing force from a surface of the inserted external terminal opposite to a surface in contact with the terminal contact portion. The case is provided with a first insertion portion into which the external terminal is inserted.

### CROSS-REFERENCE TO RELATED APPLICATION(S)

This application is based on and claims priority under 35 USC 119 from Japanese Patent Application No. 2023-110560 filed on Jul. 5, 2023, the contents of which are incorporated herein by reference.

### TECHNICAL FIELD

The present invention relates to a semiconductor module and a semiconductor device.

### BACKGROUND ART

There is a semiconductor device in which terminals provided on a case that accommodates a wiring board on which a semiconductor element is mounted and a conductor pattern of the wiring board or a connecting conductor provided on the conductor pattern are joined by ultrasonic joining or laser welding (for example, WO2022/049660 and WO2009/081723).

The joining methods such as ultrasonic joining and laser welding described above increase a size of the semiconductor device and the manufacturing cost.

### SUMMARY

The present invention has been made in view of the above situations, and an object thereof is to reduce a size of a semiconductor device while suppressing an increase in manufacturing cost.

An aspect of the present invention provides a semiconductor module including a semiconductor element, a conductor pattern having a terminal contact portion electrically connected to the semiconductor element, a sealing body provided to seal the semiconductor element and having an upper surface from which the terminal contact portion is exposed, a case provided with an accommodating portion configured to accommodate the sealing body, and an elastic member that, when an external terminal is inserted, applies a pressing force from a surface of the inserted external terminal opposite to a surface in contact with the terminal contact portion, in which the case is provided with a first insertion portion into which the external terminal is inserted.

In addition, an aspect of the present invention provides a semiconductor device including a semiconductor element, a conductor pattern having a terminal contact portion electrically connected to the semiconductor element, a sealing body provided to seal the semiconductor element and having an upper surface from which the terminal contact portion is exposed, a case provided with an accommodating portion configured to accommodate the sealing body, an elastic member that, when an external terminal is inserted, applies a pressing force from a surface of the inserted external terminal opposite to a surface in contact with the terminal contact portion, and the external terminal sandwiched between the elastic member and the terminal contact portion and electrically connected to the terminal contact portion, in which the case is provided with a first insertion portion into which the external terminal is inserted.

According to the present invention, it is possible to reduce a size of a semiconductor device while suppressing an increase in manufacturing cost.

### BRIEF DESCRIPTION OF DRAWINGS

FIG. 1 is a plan view of a semiconductor device of a first embodiment.

FIG. 2 is a side view (1 thereof) of the semiconductor device of the first embodiment.

FIG. 3 is a side view (2 thereof) of the semiconductor device of the first embodiment.

FIG. 4 is a plan view showing an internal configuration of a semiconductor package included in the semiconductor device of the first embodiment.

FIG. 5 is a cross-sectional view showing the internal configuration of the semiconductor package included in the semiconductor device of the first embodiment.

FIG. 6 is a cross-sectional view of the semiconductor device of the first embodiment.

FIGS. 7A to 7D are views showing an external terminal included in the semiconductor device of the first embodiment.

FIG. 8 is a view illustrating states of an external terminal, a spring plate, and a terminal contact portion included in the semiconductor device of the first embodiment.

FIG. 9 is a cross-sectional view of a main part illustrating a state in which a tool is inserted in the semiconductor device of the first embodiment.

FIG. 10 is a cross-sectional view of a main part showing Variation 1 of the semiconductor device of the first embodiment.

FIG. 11 is a cross-sectional view of a main part of a semiconductor device of a second embodiment.

FIG. 12 is a cross-sectional view of a main part showing Variation 1 of the semiconductor device of the second embodiment.

FIG. 13 is a side view of the main part of Variation 1 of the semiconductor device of the second embodiment.

FIG. 14 is a cross-sectional view of a main part showing Variation 2 of the semiconductor device of the second embodiment.

FIG. 15 is a cross-sectional view of a main part showing Variation 3 of the semiconductor device of the second embodiment.

FIG. 16 is a cross-sectional view of a main part showing Variation 4 of the semiconductor device of the second embodiment.

### DESCRIPTION OF EMBODIMENTS

Hereinafter, embodiments of the present invention will be described in detail with reference to the drawings. Note that the X, Y, and Z axes in each of the referenced drawings are shown for defining a plane and a direction in the example semiconductor device and the like, are orthogonal to each other, and form a right-handed system. In the following description, the Z direction may be referred to as a vertical direction. In addition, a plane including the X and Y axes may be called an XY plane, a plane including the Y and Z axes may be called a YZ plane, and a plane including the Z and X axes may be called the ZX plane. These directions and planes are phrases used for convenience of description, and the correspondence to each of the XYZ directions may change depending on the mounting posture of the semiconductor device. For example, in the present specification, a cooler side of the semiconductor device is referred to as a bottom and an opposite side thereto is referred to as a top. However, the cooler side may be referred to as the top and the opposite side thereto may be referred to as the bottom. In addition, in the present specification, a plan view means when an upper or lower surface (XY plane) of the semiconductor device or the like is viewed in the Z direction. Additionally, the aspect ratio and the magnitude relationship between the respective members in each drawing are only schematically shown and do not necessarily match the relationship in a semiconductor device or the like that is actually manufactured. For convenience of description, it is also assumed that the magnitude relationship between the respective members is exaggerated.

### First Embodiment

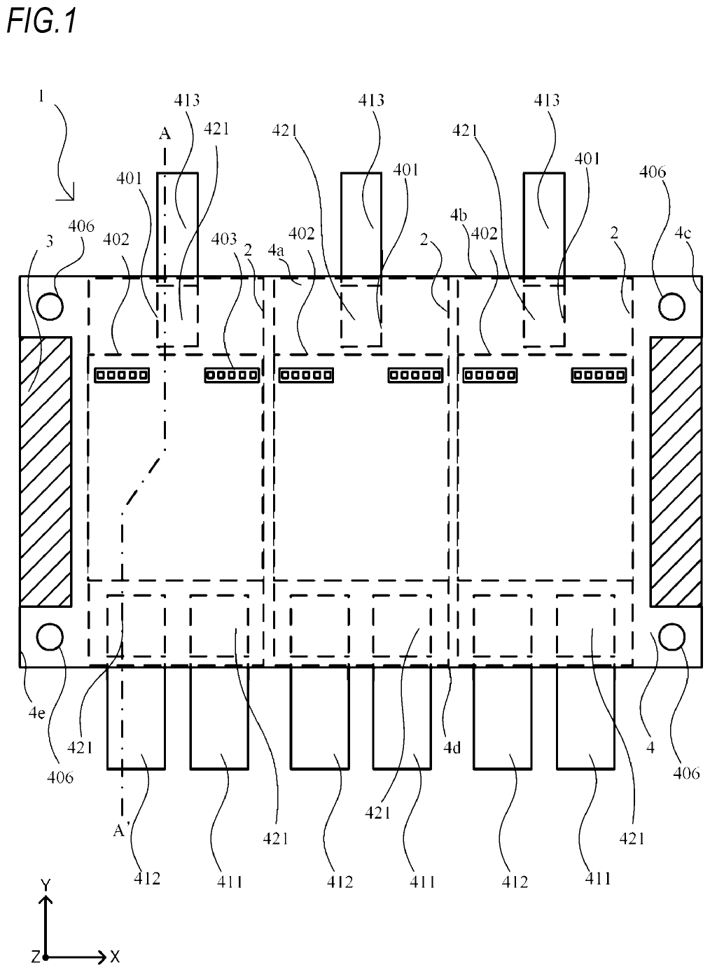

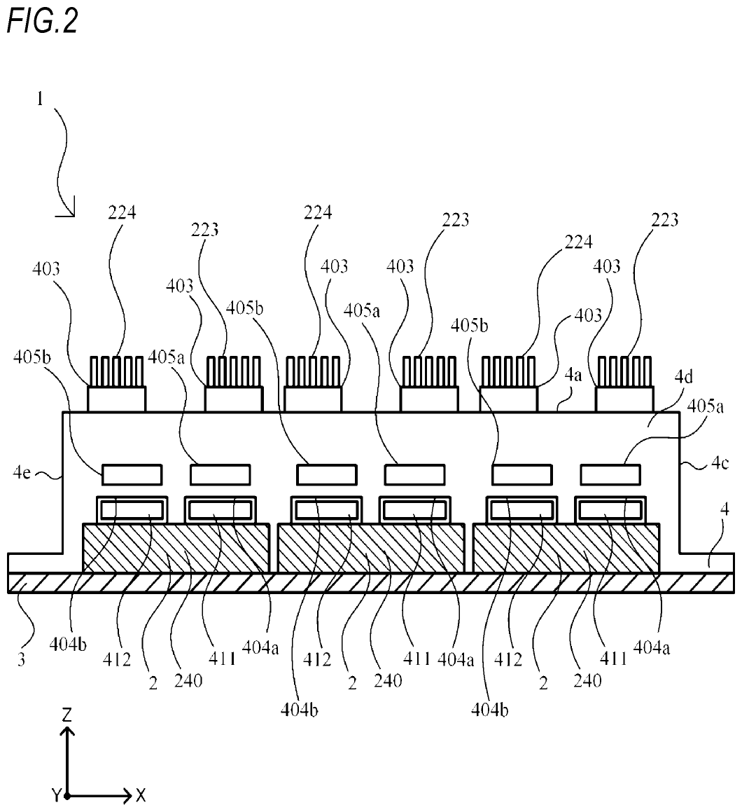

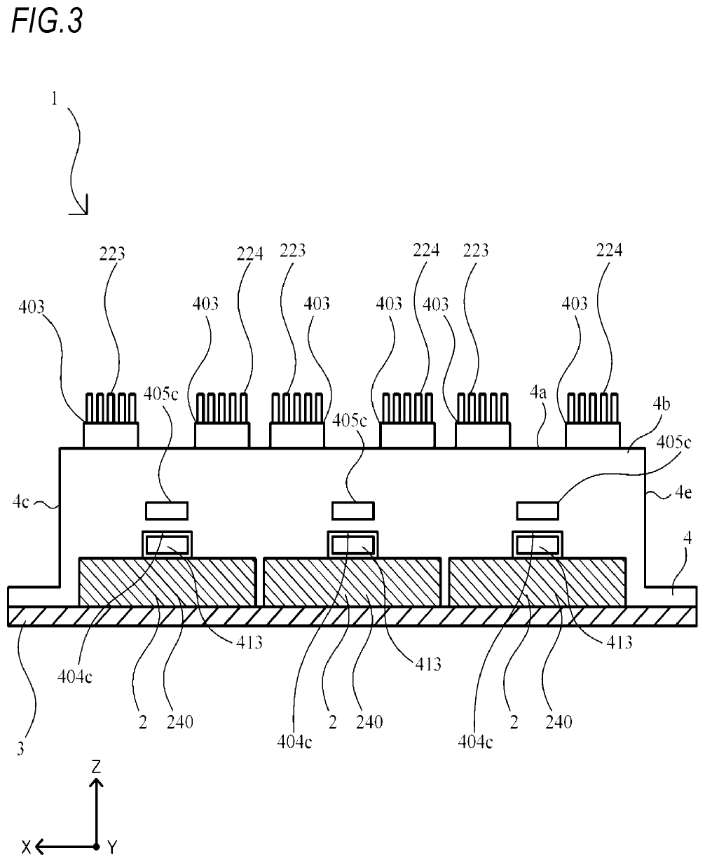

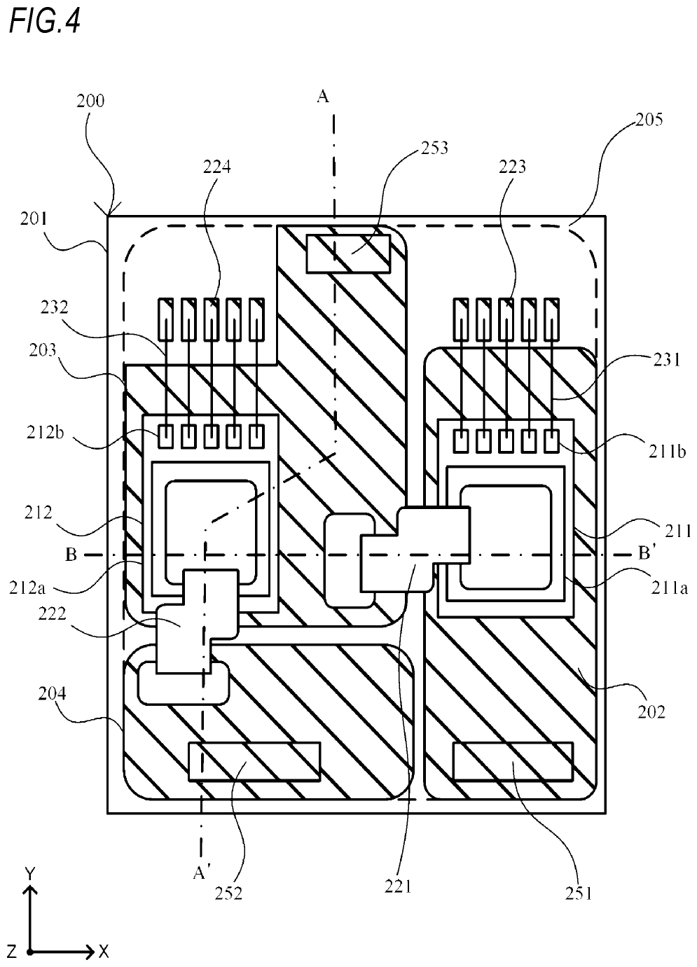

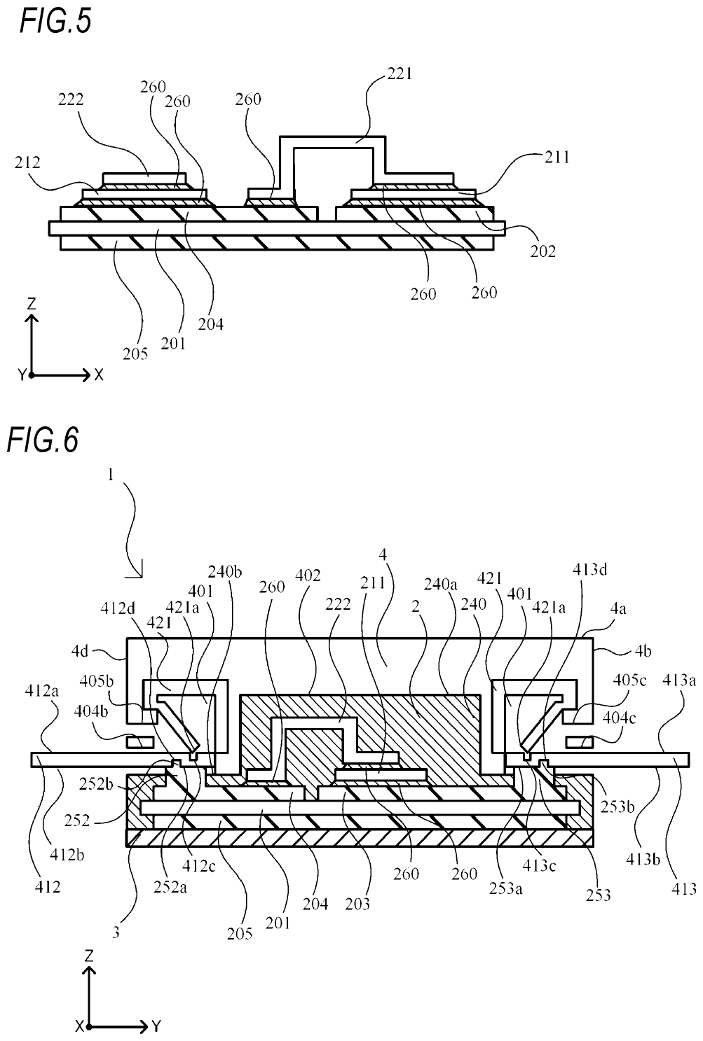

An internal configuration of a semiconductor device 1 and a semiconductor package 2 of a first embodiment will be described using FIGS. 1 to 5. FIG. 1 is a plan view of a semiconductor device 1 of a first embodiment. FIG. 2 is a side view of the semiconductor device 1 of FIG. 1, as viewed in the +Y direction. FIG. 3 is a side view of the semiconductor device 1 of FIG. 1, as viewed in the −Y direction. FIG. 4 is a plan view showing an internal configuration of a semiconductor package 2 included in the semiconductor device 1 of the first embodiment. FIG. 5 is a cross-sectional view of the semiconductor package 2 of FIG. 4 taken along a dashed-dotted line B-B′, as viewed in the Y direction.

In FIG. 1, the semiconductor device 1 includes three semiconductor packages 2, a cooler 3, a case 4, a control circuit (not shown), and external terminals 411 to 413. The semiconductor package 2 includes a wiring board 200, semiconductor elements 211 and 212, leads 221 to 224, bonding wires 231 and 232, and a sealing body 240, which will be described below. Note that each semiconductor package 2 has the same or similar configuration. The details of the semiconductor package 2 will be described below.

The cooler 3 radiates heat from the semiconductor package 2 to the outside and has, for example, a rectangular parallelepiped shape. Although not shown, the cooler 3 is configured by providing a plurality of fins on a lower surface side of a base part having a flat plate shape and accommodating the fins in a water jacket. Note that the shape and configuration of the cooler 3 are not limited thereto and can be changed appropriately. In addition, the semiconductor package 2 may be arranged on an upper surface of a separate member (for example, a base plate) from the cooler 3, and a lower surface of the separate member may be connected to the cooler 3.

The case 4 has a substantially rectangular shape in a plan view and is a member that covers the semiconductor package 2 arranged on the cooler 3. In addition, the case 4 is surrounded by an upper surface 4a and side surfaces 4b, 4c, 4d, and 4e. The side surfaces 4b and 4d correspond to long sides of the case 4, and the side surfaces 4c and 4e correspond to short sides of the case 4. In a plan view, corner portions of connection locations of the side surfaces 4b, 4c, 4d, and 4e may not be substantially right angles, and may be R-chamfered, for example.

The upper surface 4a of the case 4 has through-holes 403 through which the leads 223 and 224 pass, and fixing holes 406 for fixing the case 4 and the cooler 3 to corner portions of the upper surface 4a. The fixing hole 406 is a through-hole facing toward the cooler 3 from the upper surface 4a, and a screw (not shown) for fixing is inserted therein. Note that the fixing hole 406 may be formed on the cooler 3 side (−Z direction) with respect to the upper surface 4a. In addition, the shape and number of the through-holes 403 can be changed appropriately in accordance with the leads 223 and 224.

As shown in FIG. 2, the side surface 4d of the case 4 is formed with first insertion portions 404a and 404b into which the external terminals 411 and 412 are inserted and second insertion portions 405a and 405b into which a tool 5 described below is inserted. In addition, as shown in FIG. 3, the side surface 4b is formed with first insertion portions 404c into which the external terminals 413 are inserted and second insertion portions 405c into which the tool 5 is inserted. In the following description, when it is not necessary to distinguish among the first insertion portions 404a, 404b, and 404c, they are referred to as the first insertion portion 404, and when it is not necessary to distinguish among the second insertion portions 405a, 405b, and 405c, they are referred to as the second insertion portion 405. Additionally, the sealing body 240 of the semiconductor module 2 is exposed from the side surfaces 4b and 4d. However, the present invention is not limited thereto, and the side surfaces 4b and 4d may be formed to cover the sealing body 240.

The first insertion portion 404 has a dent shape that is open on the cooler 3 side in a side view seen in the Y direction. As shown in FIG. 2, the first insertion portions 404a and 404b are formed along the side surface 4d (X direction). As shown in FIG. 3, the first insertion portions 404c are formed along the side surface 4b (X direction). Note that a width (X direction) and a height (Z direction) of the first insertion portion may have such dimensions that the external terminals 411, 412, and 413 can be inserted. In addition, the shape of the first insertion portion 404 can be changed appropriately in accordance with shapes of the external terminals 411, 412, and 413.

The second insertion portion 405 has a rectangular shape in a side view as seen in the Y direction. The second insertion portions 405a and 405b are formed along the side surface 4d. The second insertion portions 405c are formed along the side surface 4b (X direction). The second insertion portion 405 is arranged alongside the first insertion portion 404 on the upper surface 4a side (+Z direction side) of the case 4 with respect to the first insertion portion 404. That is, the first insertion portion 404 is provided on the terminal contact portions 251 to 253 side, which will be described below, with respect to the second insertion portion 405. Note that the dimension and shape of the second insertion portion 405 can be changed appropriately in accordance with the tool 5 described below.

Here, the semiconductor package 2 will be described. As shown in FIGS. 4 and 5, the semiconductor package 2 includes a wiring board 200, semiconductor elements 211 and 212, leads 221 to 224, bonding wires 231 and 232, and a sealing body 240.

As shown in FIG. 4, the wiring board 200 includes an insulating substrate 201, conductor patterns 202 to 204 provided on an upper surface of the insulating substrate 201, and a conductor pattern 205 provided on a lower surface of the insulating substrate 201. The wiring board 200 may be, for example, a direct copper bonding (DCB) substrate or an active metal brazing (AMB) substrate. The wiring board 200 may also be called, for example, a laminated substrate, an insulated circuit substrate, or the like.

The insulating substrate 201 has a rectangular shape in a plan view. In addition, corner portions of the insulating substrate 201 may be R-chamfered or C-chamfered. The insulating substrate 201 may be a ceramic substrate formed of a ceramic material such as aluminum oxide (Al₂O₃), aluminum nitride (A1N), silicon nitride (Si₃N₄), aluminum oxide (Al₂O₃), and zirconium oxide (ZrO₂). The insulating substrate 201 may also be, for example, a substrate obtained by molding an insulating resin such as epoxy resin, a substrate in which a base material such as glass fiber is impregnated with an insulating resin, a substrate in which a surface of a metal core having a flat plate shape is coated with an insulating resin, or the like.

The conductor patterns 202 to 205 are formed of, for example, a metal plate or metal foil such as copper or aluminum. The conductor patterns 202 to 205 may also be called a conductor layer, a conductor plate, a conductive layer, or a wiring pattern. In the following description, when distinguishing among the conductor patterns 202 to 205, each is referred to as a first conductor pattern 202, a second conductor pattern 203, a third conductor pattern 204, and a fourth conductor pattern 205.

The semiconductor element 211 is arranged on an upper surface of the first conductor pattern 202. In addition, the semiconductor element 212 is arranged on an upper surface of the second conductor pattern 203. As shown in FIG. 5, the first conductor pattern 202 is joined to a first main electrode (not shown) provided on a lower surface of the semiconductor element 211 by a joining material 260. The second conductor pattern 203 is joined to a first main electrode (not shown) provided on a lower surface of the semiconductor element 212 by the joining material 260. The joining material 260 may be a solder or a sintered material. The solder may be a lead-free solder. The lead-free solder has, as a main component, an alloy containing at least two of tin (Sn), silver (Ag), copper (Cu), zinc (Zn), antimony (Sb), indium (In), and bismuth (Bi), for example. In addition, the solder may contain an additive. The additive is, for example, nickel (Ni), germanium (Ge), cobalt (Co), or silicon (Si). The additive is contained in the solder, resulting in improvements in wettability, gloss, bonding strength, and reliability. As the sintered material, for example, a metal material including silver, copper, or an alloy containing at least one of silver and copper is used.

Each of the semiconductor elements 211 and 212 is, for example, a switching element such as an insulated gate bipolar transistor (IGBT) element or a metal oxide semiconductor field effect transistor (MOSFET), or a diode element such as a free wheeling diode (FWD) element. In addition, the semiconductor element may be configured by a reverse conducting (RC)-IGBT element in which functions of a switching element such as an IGBT element and functions of a diode element such as a FWD element are integrated. Each of these types of semiconductor elements 211 and 212 has a first main electrode provided on the lower surface, and a second main electrode and a control electrode (gate electrode) provided on the upper surface. Each of the above elements may be formed on a silicon (Si) substrate. Additionally, a wide band gap semiconductor formed on a substrate using silicon carbide (SiC) or the like may be used.

As shown in FIG. 5, the lead 221 is a wiring member formed by bending a conductor plate such as a copper plate, and is joined to a surface electrode 211a on the upper surface of the semiconductor element 211 and the second conductor pattern 203 by the joining material 260. That is, the surface electrode 211a of the semiconductor element 211 is electrically connected to the second conductor pattern 203 via the lead 221. The first conductor pattern 202 has a terminal contact portion 251 that is electrically connected to the external terminal 411.

The lead 222 is a wiring member formed by bending a conductor plate such as a copper plate, and is joined to a surface electrode 212a on the upper surface of the semiconductor element 212 and the third conductor pattern 204 by the joining material 260. That is, the surface electrode 212a of the semiconductor element 212 is electrically connected to the third conductor pattern 204 via the lead 222. The second conductor pattern 203 has a terminal contact portion 253 that is electrically connected to the external terminal 413.

The third conductor pattern 204 has a terminal contact portion 252 that is electrically connected to the external terminal 412. Note that the first conductor pattern 202, the second conductor pattern 203, and the third conductor pattern 204 are examples. The numbers, shapes, sizes, and positions of the first conductor pattern 202, the second conductor pattern 203, and the third conductor pattern 204 may be appropriately selected as necessary.

In FIG. 4, the control electrode 211b provided on the upper surface of the semiconductor element 211 is electrically connected to the lead 223 by the bonding wire 231. The control electrode 212b provided on the upper surface of the semiconductor element 212 is electrically connected to the lead 224 by the bonding wire 232. The leads 223 and 224 are bent, for example, into an L shape, and one end portions thereof are joined to the insulating substrate 201 and the other end portions protrude from an upper surface 240a of the sealing body 240, which will be described below, and extend upward. The leads 223 and 224 are wiring members formed using a conductor plate such as a copper plate. The other end portions of the leads 223 and 224 protruding from the upper surface 240a of the sealing body 240 and extending upward pass through the through-holes 403 provided in the case 4 and are connected to a control circuit (not shown) arranged on the case 4. Note that the numbers of the leads 223 and 224 may correspond to the control electrodes 211b and 212b of the semiconductor elements 211 and 212 and are not limited to five.

The conductor patterns 202 to 204 of the wiring board 200, the semiconductor elements 211 and 212, the entire leads 221 and 222, a portion of the lead 223, and a portion of the lead 224 are sealed by the sealing body 240. The semiconductor package 2 of the first embodiment is manufactured by, for example, a transfer mold.

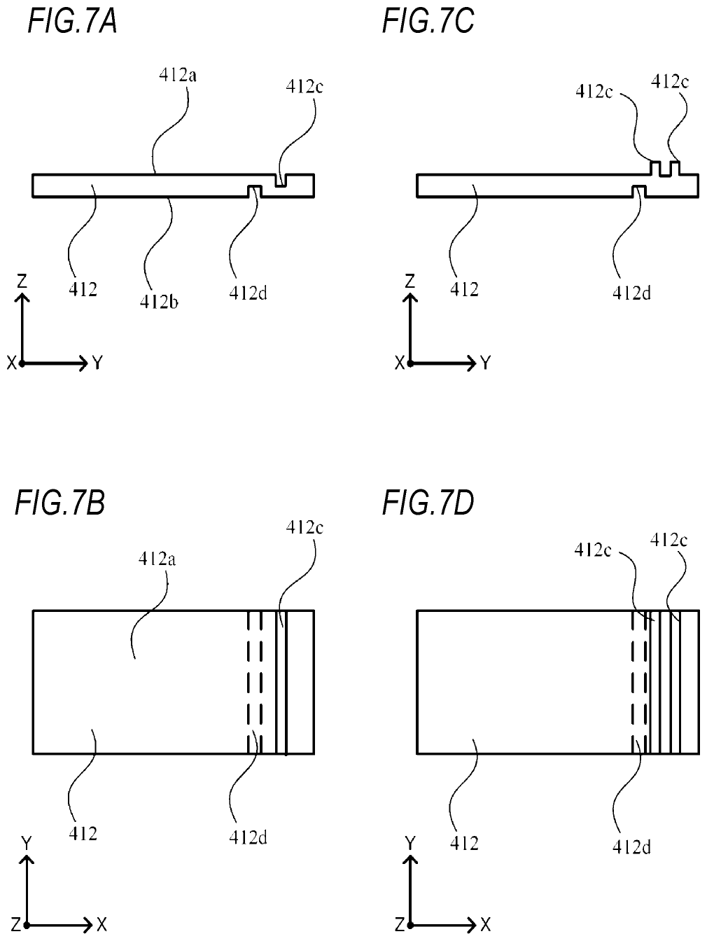

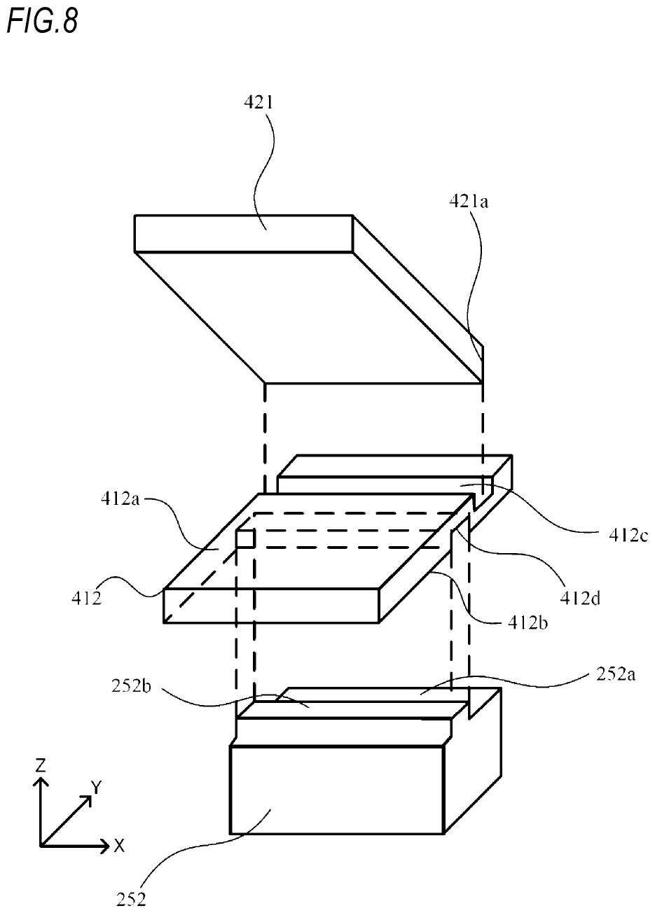

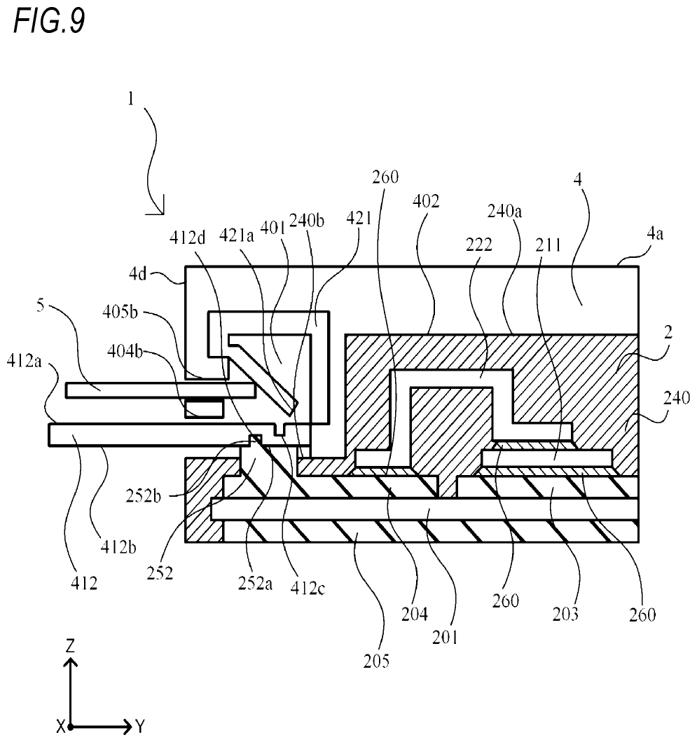

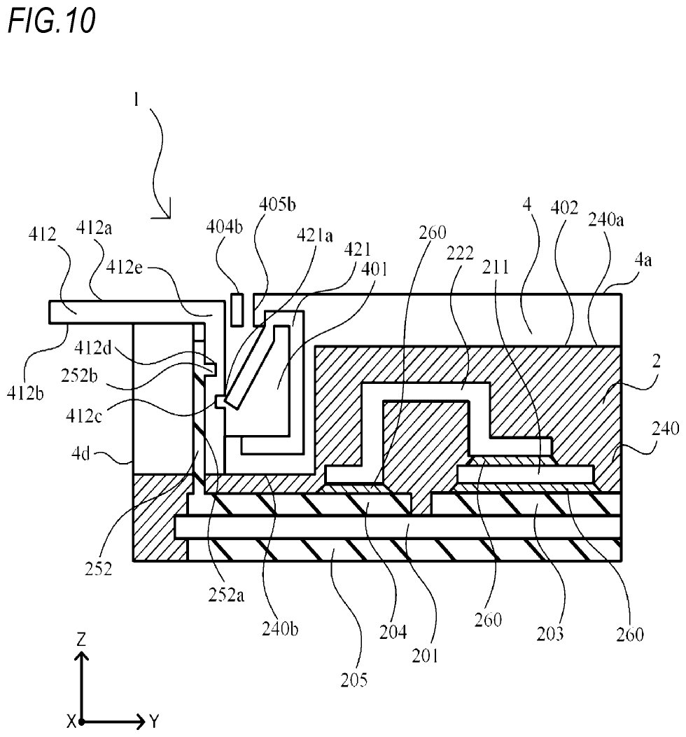

Next, fixation of the external terminal and the terminal contact portion will be described using FIGS. 6 to 9. FIG. 6 is a cross-sectional view of the semiconductor device 1 of FIG. 1 taken along a dashed-dotted line A-A′, as viewed in the −X direction. FIGS. 7A to 7D are views showing a configuration of an external terminal included the semiconductor device 1. FIG. 8 is a view illustrating states of an external terminal, a spring plate, and a terminal contact portion included in the semiconductor device 1. FIG. 9 is a cross-sectional view of a main part illustrating a state in which the tool 5 is inserted in the semiconductor device 1.

FIG. 6 shows a cross-sectional view of the semiconductor device 1 of FIG. 1 taken along a dashed-dotted line A-A′, as viewed in the −X direction. The terminal contact portion 252 of the semiconductor package 2 forms a pillar shape extending from the surface of the third conductor pattern 204 toward the case 4 side (+Z direction), and has a surface 252a in contact with a rear surface 412b of the external terminal 412 and a protrusion 252b that is introduced into a groove portion 412d of the external terminal 412. The protrusion 252b extends from the surface 252a toward the upper surface 4a side of the case 4. The protrusion 252b may have a pillar shape, for example.

The sealing body 240 has an upper surface 240a and a step portion 240b in which end portions of the upper surface 240a on the side surfaces 4b and 4d sides of the case 4 are concave toward the cooler 3 side. The terminal contact portion 252 is exposed from an upper surface of the step portion 240b toward the case 4 side (+Z direction). Note that if the upper surface of the terminal contact portion 252 is exposed from the upper surface 240a of the sealing body 240, the step portion 240b does not need to be provided. The terminal contact portions 251 (not shown) and 253 have the same or similar configuration as or to the terminal contact portion 252. Note that as long as the terminal contact portions 251 to 253 are exposed from the upper surface 240a or step portion 240b of the sealing body 240, heights (Z direction) thereof are not particularly limited.

The case 4 has spring plate accommodating portions 401 that accommodate spring plates 421 and accommodating portions 402 that accommodate the semiconductor packages 2. As shown in FIG. 1, the spring plate accommodating portion 401 has a rectangular shape in a plan view. The accommodating portion 402 has a rectangular shape in a plan view. The spring plate accommodating portions 401 are arranged alongside the first insertion portions 404 in the Y direction on the side surfaces 4b and 4d. The accommodating portion 402 is arranged in a region sandwiched between the spring plate accommodating portion 401 provided on the side surface 4b side and the spring plate accommodating portion 401 provided on the side surface 4d side. In addition, as shown in FIG. 6, the spring plate accommodating portion 401 and the accommodating portion 402 of the case 4 define a concave space in which a side toward the cooler 3 (−Z direction) is open. The spring plate accommodating portion 401 is provided at a position (+Z direction) facing the terminal contact portion 252. That is, the spring plate accommodating portion 401 is provided on a side of the step portion 240b of the sealing body 240 opposite to a side on which the cooler 3 is located. The accommodating portion 402 accommodates the upper surface 240a of the sealing body 240. Each spring plate accommodating portion 401 has the same or similar structure. The spring plate accommodating portion 401 is provided continuously with the first insertion portion 404 and the second insertion portion 405. That is, the first insertion portion 404 and the second insertion portion 405 penetrate from the side surface 4b or 4d of the case 4 toward the spring plate accommodating portion 401 and the spring plate 421.

A spring plate 421 is accommodated in the spring plate accommodating portion 401 of the case 4. The spring plate 421 is arranged at a position (+Z direction) facing the terminal contact portion 252. The spring plate 421 has a contact portion 421a at an end portion, which comes into contact with a front surface 412a of the external terminal 412 when the external terminal 412 is inserted into the first insertion portion 404 of the case 4. The spring plate 421 applies a pressing force to bring the external terminal 412 into contact with the terminal contact portion 252, as will be described below, and is preferably formed of an elastic member that can continuously apply the pressing force. For example, the spring plate 421 may be made of metal such as copper or aluminum as an elastic member. In addition, the spring plate 421 may be made of rubber or the like as long as it can maintain a stable pressing force.

The external terminal 411 is, for example, an input terminal (N terminal). An inner end portion of the external terminal 411 is inserted into the first insertion portion 404a of the case 4 and is electrically connected to the terminal contact portion 251 of the first conductor pattern 202. An outer end portion of the external terminal 411 is exposed to the outside from the side surface 4d of the case 4.

The external terminal 412 is, for example, an input terminal (P terminal). An inner end portion of the external terminal 412 is inserted into the first insertion portion 404b of the case 4 and is electrically connected to the terminal contact portion 252 of the third conductor pattern 204. An outer end portion of the external terminal 412 is exposed to the outside from the side surface 4d of the case 4.

The external terminal 413 is, for example, an output terminal (one of a U-phase output terminal, a V-phase output terminal, and a W-phase output terminal). An inner end portion of the external terminal 413 is inserted into the first insertion portion 404c of the case 4 and is electrically connected to the terminal contact portion 253 of the second conductor pattern 203. An outer end portion of the external terminal 413 is exposed to the outside from the side surface 4b of the case 4.

The external terminals 411 and 412 are, for example, terminals provided for capacitors (not shown). The external terminal 413 is a terminal provided for a load that operates by alternating current of an alternating current motor (not shown) or the like, for example.

FIGS. 7A to 7D are views illustrating a configuration of an external terminal. FIGS. 7A to 7D show configurations of the external terminal 412 as an example of an external terminal. FIG. 7A is a side view of an example of an external terminal, and FIG. 7B is a top view of the example of the external terminal. Additionally, FIG. 7C is a side view of another example of an external terminal, and FIG. 7D is a plan view of another example of the external terminal. As shown in FIG. 7A, the external terminal 412 has a front surface 412a on the spring plate 421 side (+Z side) and a rear surface 412b on the terminal contact portion 252 side (−Z side) of the third conductor pattern 204. Additionally, the front surface 412a has a fixing portion 412c that is concave from the front surface 412a toward the rear surface 412b. The rear surface 412b has a groove portion 412d that is concave from the rear surface 412b toward the front surface 412a. As shown in FIG. 7B, the fixing portion 412c and the groove portion 412d each have a rectangular shape in a plan view, but are not particularly limited. In addition, widths (X direction) of the fixing portion 412c and the groove portion 412d are equal to a width of the external terminal 412. The fixing portion 412c and the groove portion 412d are provided without overlapping in a plan view. Note that as shown in FIG. 7C, the fixing portion 412c may be a plurality of protruding convex portions. Additionally, as shown in FIG. 7D, the fixing portion 412c, which is a plurality of protruding convex portions, has a width equal to the width of the external terminal 412. The fixing portion 412c and the groove portion 412d are provided without overlapping in a plan view.

FIG. 8 is a view (an exploded perspective view) showing a positional relationship of fitting among the external terminal 412, the spring plate 421, and the terminal contact portion 252 of the first conductor pattern 204. The surface 252a of the terminal contact portion 252 is in contact with the rear surface 412b of the external terminal 412. The protrusion 252b of the terminal contact portion 252 is introduced into the groove portion 412d of the external terminal 412. The contact portion 421a of the spring plate 421 comes into contact with the fixing portion 412c of the external terminal 412. A width (X direction) of the terminal contact portion 252 is approximately equal to the width (X direction) of the external terminal 412. A width (X direction) of the protrusion 252b is approximately equal to the width (X direction) of the groove portion 412d of the external terminal 412. A height (Z direction) of the protrusion 252b is designed to be such a height that the rear surface 412b can come into contact with the surface 252a of the terminal contact portion 252 when the protrusion is introduced into the groove portion 412d of the external terminal 412. A width (X direction) of the spring plate 421 is approximately equal to the width (X direction) of the fixing portion 412c of the external terminal 412. The protrusion 252b of the terminal contact portion 252 and the groove portion 412d of the external terminal 412 may be provided in plural.

Note that although detailed description is omitted, the terminal contact portion 251 of the first conductor pattern 202 of the semiconductor package 2 and the external terminal 411, the terminal contact portion 253 of the second conductor pattern 203 of the semiconductor package 2 and the external terminal 413, the terminal contact portion 253 of the third conductor pattern 204 of the semiconductor package 2 and the external terminal 412, and the respective spring plates 421 have the same or similar configuration, arrangement, and dimension.

As shown in FIGS. 6 and 8, when the external terminals 411 to 413 are inserted into the first insertion portions 404a to 404c of the case 4, the front surfaces 411a to 413a of the external terminals 411 to 413 and the contact portions 421a of the spring plates 421 come into contact with each other, and the rear surfaces 411b to 413b and the surfaces 251a to 253a of the terminal contact portions 251 to 253 of the conductor patterns 202 to 204 come into contact with each other. At this time, the spring plates 421 apply a pressing force to the front surfaces 411a to 413a of the external terminals 411 to 413 toward the contact terminal portions 251 to 253 side. The external terminals 411 to 413 and the terminal contact portions 251 to 253 are mechanically and electrically connected by the pressing force applied from the spring plates 421. Therefore, the semiconductor device 1 of the first embodiment can secure electrical connection between the external terminals 411 to 413 and the conductor patterns 202 to 204 of the wiring board 200 of the semiconductor package 2 without performing laser welding, ultrasonic joining, or the like. In addition, the contact portions 421a of the spring plates 421 are in contact with the fixing portions 411c to 413c of the external terminals 411 to 413. Thereby, the contact portions 421a of the spring plates 421 are caught by the fixing portions 411c to 413c, so the mechanical connection between the external terminals 411 to 413 and the terminal contact portions 251 to 253 can be strengthened.

Additionally, the protrusions 251b to 253b of the terminal contact portions 251 to 253 are introduced into the groove portions 411d to 413d of the external terminals 411 to 413. Thereby, the protrusions 251b to 253b are caught in the groove portions 411d to 413d, so the external terminals 411 to 413 and the terminal contact portions 251 to 253 can be positionally aligned, and the mechanical connection between the external terminals 411 to 413 and the terminal contact portions 251 to 253 can be strengthened.

The case 4 includes the spring plates 421, and is integrally molded by injection molding using a thermoplastic resin, for example. The thermoplastic resin is, for example, a polyphenylene sulfide resin, a polybutylene terephthalate resin, a polybutylene succinate resin, a polyamide resin, or an acrylonitrile butadiene styrene resin. Additionally, the case 4 is molded from an epoxy resin, for example.

Next, a manufacturing process of the semiconductor package 2 will be described. The manufacturing process of the semiconductor package 2 roughly includes, for example, a process of manufacturing the wiring board 200, a process of forming a circuit by arranging the semiconductor elements 211 to 212 and the leads 221 to 224 on the upper surface of the wiring board 200, and sealing the circuit on the wiring board 200.

The process (not shown) of sealing the circuit on the wiring board 200 is performed using, for example, a transfer mold. A circuit board where the circuit formed by the semiconductor elements 211 and 212, the leads 221 and 222, and the like is formed on the upper surface of the wiring board 200 is placed in a space (cavity) defined by a lower die and an upper die of a mold. The lower die is provided with a concave wiring board accommodating portion having a bottom surface in close contact with the lower surface of the fourth conductor pattern 205 of the wiring board 200, for example. The upper die is formed with a wall portion for forming a dent shape of an end portion of the sealing body 240 of the semiconductor package 2 described above. The wall portion defines a concave portion shaped to include the terminal contact portions 251 to 253 of the conductor patterns 202 to 204. By using such a lower die and an upper die, the semiconductor package 2 in which the terminal contact portions 251 to 253 are exposed from the upper surface of the step portion 240b of the sealing body 240 when the sealing body 240 is introduced into the cavity can be manufactured. Note that the method of sealing the semiconductor elements 211 and 212 on the wiring board 200 with an insulating material is not limited to the transfer mold described above.

When manufacturing a semiconductor device of the related art, for example, a process of electrically connecting a conductor pattern of a wiring board on which a circuit is formed by arranging semiconductor elements and the like and an external terminal provided for a case having an open upper surface is performed, and then, a process of sealing the semiconductor elements and the like in the case by an insulating resin is performed. In such a manufacturing process, the conductor pattern of the wiring board and the external terminal are joined by laser welding or ultrasonic joining.

However, in laser welding, damage to the insulating substrate of the wiring board and leakage of a joining material (for example, solder) due to heat may occur. For this reason, the terminal contact portion needs to have a certain height (dimension in the Z direction). In addition, in ultrasonic joining, an area where the external terminal and the conductor pattern can be joined by single processing is limited, and a joining area between the conductor pattern of the wiring board and the conductive member of the case increases.

In contrast, in the semiconductor device 1 of the first embodiment, the external terminals 411 to 413 inserted into the first insertion portions 404a to 404b of the case 4 and the terminal contact portions 251 to 253 provided on the conductor patterns 202 to 204 are mechanically connected by the pressing force applied from the spring plates 421. That is, the terminal contact portions 251 to 253 do not need to have a height (dimension in the Z direction) in order to prevent damage to the wiring board 200 due to laser welding, and can be suppressed to such a height that the terminal contact portions are exposed from the upper surface of the step portion 240b of the sealing body 240. In addition, the process of joining the terminal portions 251 to 253 and the external terminals 411 to 413 can be reduced. Therefore, it is possible to reduce a size of a semiconductor device while suppressing an increase in manufacturing cost.

Note that in the first embodiment, the spring plates 421 have been exemplified as a method of fixing the terminal contact portions 251 to 253 and the external terminals 411 to 413, but an elastic member may be used as the fixing method. By using an elastic member that can apply the pressing force to the spring plate accommodating portions 401 of the case 4 toward the contact terminal portions 251 to 253 side, the external terminals 411 to 413 inserted into the first insertion portions 404a to 404c of the case 4 and the terminal contact portions 251 to 253 can be connected mechanically.

FIG. 9 is a cross-sectional view of a main part for illustrating a method of removing an external terminal. A tool 5 is inserted into the second insertion portion 405b of the case 4. When inserted into the second insertion portion, the tool 5 presses the spring plate 421 toward the upper surface 4a side of the case 4 from a portion in contact with the spring plate 421. The contact portion 421a of the spring plate 421 is separated from the fixing portion 412c of the external terminal 412 toward the upper surface 4a side of the case 4 when the spring plate 421 is pressed by the tool 5. Note that the tool 5 may be of a thin plate shape that can press the spring plate 421 away from the external terminal 412, and is for example, a flat-blade (−) screwdriver.

In this way, by inserting the tool 5 into the second insertion portion 405 of the case 4, the mechanical connection between the fixing portions 411c to 413c of the external terminals 411 to 413 and the contact portion 421a of the spring plate 421 can be released. That is, it becomes possible to easily remove the external terminals 411 to 413 from the terminal contact portions 251 to 253 of the conductor patterns 202 to 204.

FIG. 10 shows a cross-sectional view of a main part illustrating Variation 1 of the semiconductor device 1 according to the first embodiment.

As shown in FIG. 10, the first insertion portion 404b and the second insertion portion 405b of the case 4 of a semiconductor device 1a of Variation 1 are provided on the upper surface 4a of the case 4. The first insertion portion 404b is provided on the terminal contact portion 252 side with respect to the second insertion portion 405b. In addition, the first insertion portion 404 and the second insertion portion 405 penetrate from the upper surface 4a of the case 4 toward the spring plate accommodating portion 401 and the spring plate 421.

The terminal contact portion 252 of the third conductor pattern 204 is exposed from the upper surface of the step portion 240b of the sealing body 240 toward the case 4 side (+Z direction). In addition, the protrusion 252b of the terminal contact portion 252 has a pillar shape protruding from the surface 252a of the terminal contact portion 252 toward the spring plate 421 side (+X direction). Additionally, a surface of the terminal contact portion 252 opposite to the surface 252a is in contact with an inner wall portion of the spring plate accommodating portion 401 of the case 4.

The external terminal 412 has a bent portion 412e bent at a substantially right angle from a portion protruding from the first insertion portion 404b toward the side surface 4d side (−X direction) of the case 4. The external terminal 412 is bent at the bent portion 412e and extends along the upper surface 4a of the case 4.

When the external terminal 412 is inserted into the first insertion portion 404b of the case 4, the front surface 412a of the external terminal 412 and the contact portion 421a of the spring plate 421 come into contact with each other, and the rear surface 412b and the surface 252a of the terminal contact portion 252 of the conductor pattern 204 come into contact with each other. At this time, the contact portion 421a of the spring plate 421 applies a pressing force to the external terminal 412 toward the contact terminal portion 252 side. Therefore, the external terminal 412 and the terminal contact portion 252 are mechanically or electrically connected by the pressing force applied via the contact portion 421a. In addition, when the external terminal 412 is attached to a capacitor or the like, a self-weight of the capacitor or the like is added to the external terminal 412 toward the cooler 3 side. That is, the external terminal 412 is pressed against the upper surface 4a of the case 4 by the self-weight of the capacitor or the like. Therefore, the holding force of the external terminal 412 can be increased.

In addition, by inserting the tool 5 into the second insertion portion 405 of the case 4, the mechanical connection between the fixing portions 411c to 413c of the external terminals 411 to 413 and the contact portion 421a of the spring plate 421 can be released. That is, it becomes possible to easily remove the external terminals 411 to 413 from the terminal contact portions 251 to 253 of the conductor patterns 202 to 204.

Note that although detailed description is omitted, the terminal contact portions 251 and 253 of the first conductor pattern 202 of the semiconductor package 2, the external terminals 411 and 413, and the first insertion portions 404a and 404c of the case 4 have the same or similar configuration, arrangement, and dimension as or to those of the terminal contact portion 252 of the third conductor pattern 204 of the semiconductor package 2, the external terminal 412, and the first insertion portion 404b of the case 4.

### Second Embodiment

A second embodiment will be described. Note that in each of aspects illustrated below, for elements whose functions are the same as or similar to those of the first embodiment, the same symbols as those in the description of the first embodiment are used and detailed descriptions thereof are appropriately omitted.

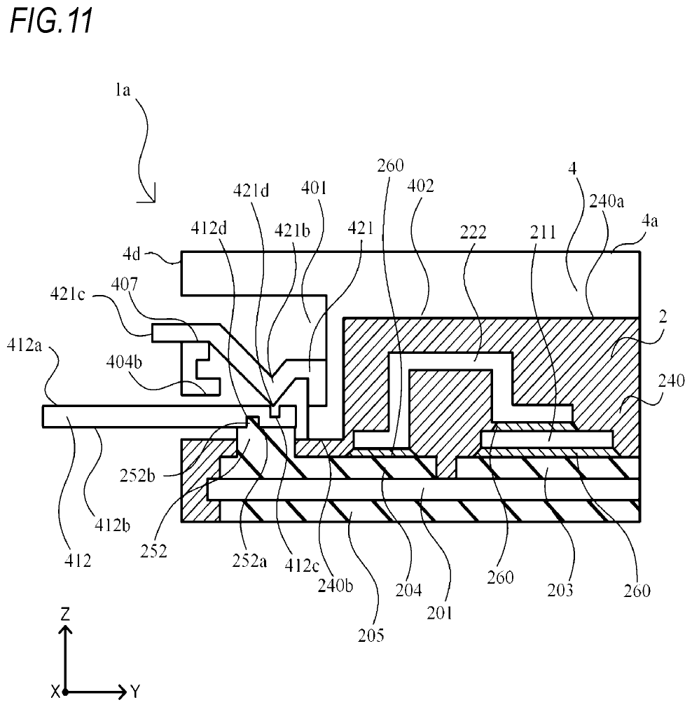

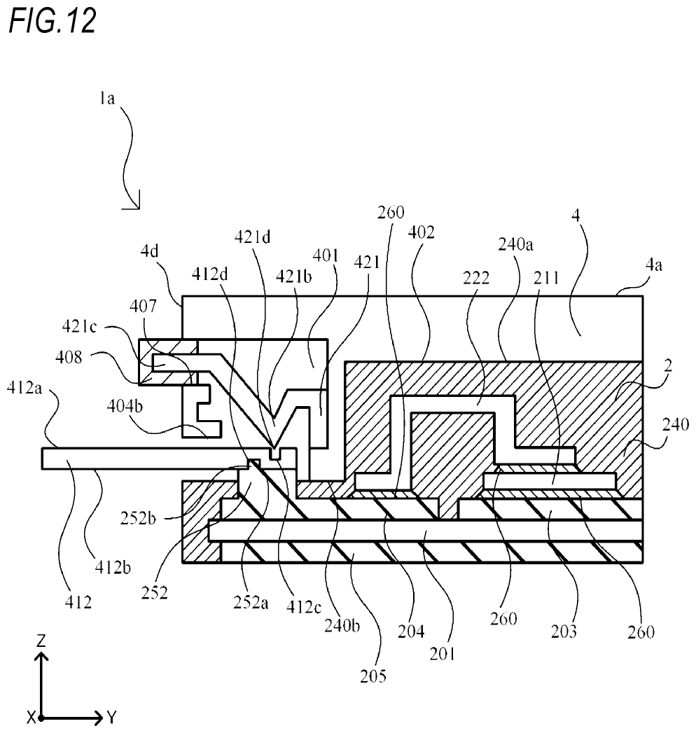

FIG. 11 shows a cross-sectional view of a main part of a semiconductor device 1a in a second embodiment. The case 4 has an opening portion 407, which has a rectangular shape when viewed in the Y direction, on the side surface 4d. The opening portion 407 is arranged alongside the first insertion portion 404b on the upper surface 4a side of the case 4 with respect to the first insertion portion 404b of the case 4. In addition, the opening portion 407 is provided continuously with the spring plate accommodating portion 401. Note that although not specifically shown, a plurality of openings 407 may be provided on the side surfaces 4b and 4d, and the respective opening portions 407 are arranged alongside the first insertion portions 404a and 404c on the upper surface 4a side with respect to the first insertion portions 404a and 404c. Each opening portion 407 has the same or similar configuration.

The spring plate 421 has a flexed portion 421b bent toward the terminal contact portion 252 side of the third conductor pattern 204 and a tip end portion 421c protruding outward from the opening portion 407 of the case 4. A vertex 421d of the flexed portion 421b is provided at a position facing the third conductor pattern 204. In addition, the spring plate 421 is not fixed to the spring plate accommodating portion 401 of the case 4. That is, the spring plate 421 is not fixed to the case 4. Additionally, a height (dimension in the Z-direction) and a width (dimension in the X-direction) of the tip end portion 421c of the spring plate 421 are smaller than a height (dimension in the Z-direction) and a width (dimension in the X-direction) of the opening portion 407.

When the external terminal 412 is inserted into the first insertion portion 404b of the case 4, the front surface 412a of the external terminal 412 and the vertex 421d of the flexed portion 421b of the spring plate 421 come into contact with each other, and the rear surface 412b and the surface 252a of the terminal contact portion 252 of the conductor pattern 204 come into contact with each other. At this time, the flexed portion 421b of the spring plate 421 applies a pressing force to the external terminal 412 toward the contact terminal portion 252 side via the vertex 421d. Therefore, the external terminal 412 and the terminal contact portion 252 are mechanically and electrically connected by the pressing force applied via the vertex 421d.

Even in such a semiconductor device 1a, electrical connection between the external terminal 412 and the conductor pattern 204 of the wiring board 200 of the semiconductor package 2 can be secured without performing laser welding or ultrasonic joining. That is, the terminal contact portion 252 does not need to have a height (dimension in the Z direction) in order to prevent damage to the wiring board 201 due to laser welding, and can be suppressed to such a height that the terminal contact portion is exposed from the upper surface of the step portion 240b of the sealing body 240. In addition, the process of joining the terminal portion 252 and the external terminal 412 can be reduced. Therefore, it is possible to reduce a size of a semiconductor device while suppressing an increase in manufacturing cost. Additionally, the vertex 421d of the spring plate 421 is in contact with the fixing portion 412c of the external terminal 412. Thereby, the vertex 412d of the spring plate 421 is caught by the fixing portion 412c, so the mechanical connection between the external terminal 412 and the terminal contact portion 252 can be strengthened.

In addition, the tip end portion 421c of the spring plate 421 is not fixed to the case 4 and protrudes from the opening portion 407. That is, the spring plate 421 is not fixed to the case 4, and the height (dimension in the Z-direction) and width (dimension in the X-direction) of the tip end portion 421c of the spring plate 421 are smaller than the height (dimension in the Z-direction) and width (dimension in the X-direction) of the opening portion 407. Thereby, the tip end portion 421c of the spring plate 421 can be lifted toward the upper surface 4a side of the case 4 by using, for example, a tool or a finger, so the mechanical connection between the fixing portion 412c of the external terminal 412 and the spring plate 421d can be released. Therefore, it becomes possible to easily remove the external terminal 412 from the terminal contact portion 252 of the conductor pattern 204.

Note that although detailed description is omitted, the terminal contact portion 251 of the first conductor pattern 202 of the semiconductor package 2 and the external terminal 411, the terminal contact portion 253 of the second conductor pattern 203 of the semiconductor package 2 and the external terminal 413, the terminal contact portion 253 of the third conductor pattern 204 of the semiconductor package 2 and the external terminal 412, and each spring plate 421 have the same or similar configuration, arrangement, and dimension.

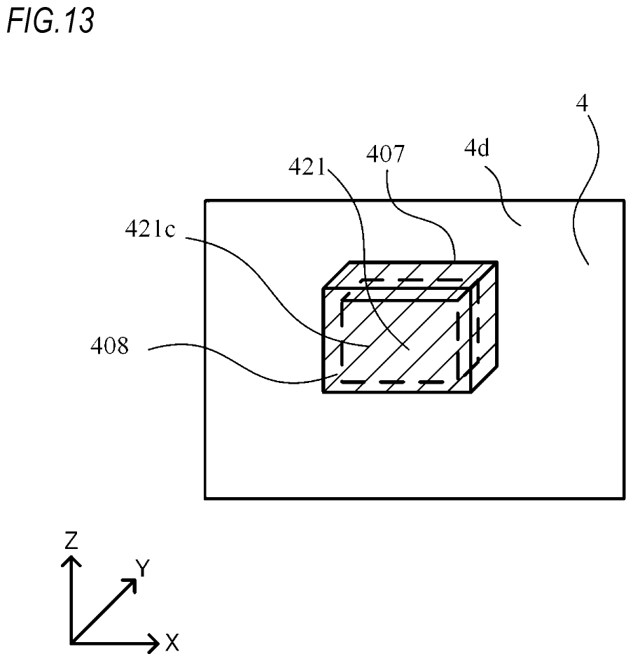

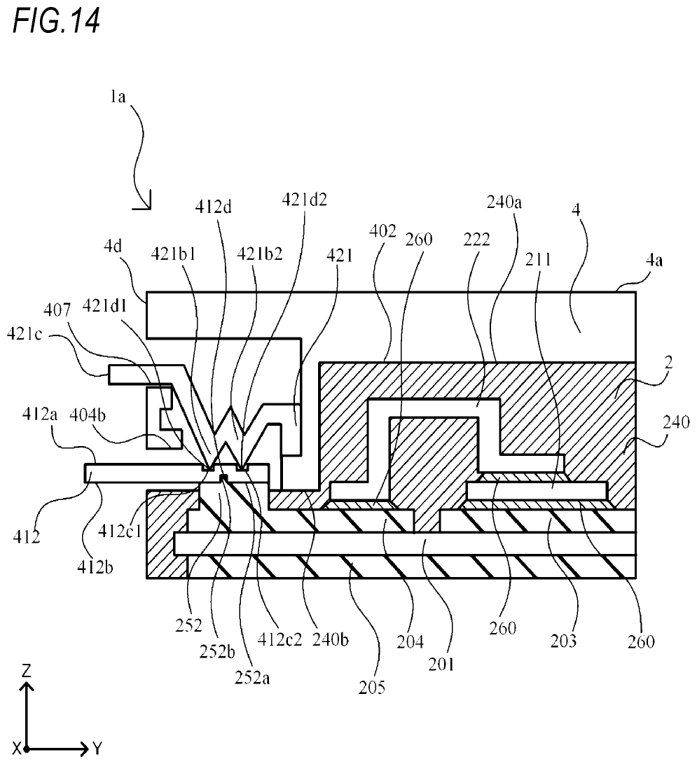

FIGS. 12 and 13 show cross-sectional views of a main part illustrating Variation 1 of the semiconductor device 1a in the second embodiment. FIG. 12 shows a side view of a main part illustrating Variation 1 of the semiconductor device 1a in the second embodiment. FIG. 13 is a side view of the main part of the semiconductor device 1a of Variation 1 of the second embodiment, as viewed in the +Y direction.

As shown in FIG. 12, a protection member 408 is attached to the opening portion 407 of the case 4 of the semiconductor device 1a of Variation 1 so as to cover the tip end portion 421c of the spring plate 421. The protection member 408 is made of the same as or similar material as or to that of the case 4, for example. The protection member 408 covers the tip end portion 421c of the spring plate 421, and a tip end portion of the protection member 408 is inserted and attached to the opening portion 407. Note that the protection member 408 may be formed integrally with the case 4.

In addition, as shown in FIG. 13, the protection member 408 has a rectangular shape in a side view. The protection member 408 surrounds and covers the tip end portion 421c of the spring plate 421 on all sides. Thereby, the insulation of the spring plate 421 can be protected when, for example, the external terminal 412 is attached to the capacitor. Note that the protection member 408 is appropriately selected to have a shape and a size that can cover the tip end portions 411c to 413c of the external terminals 411 to 413.

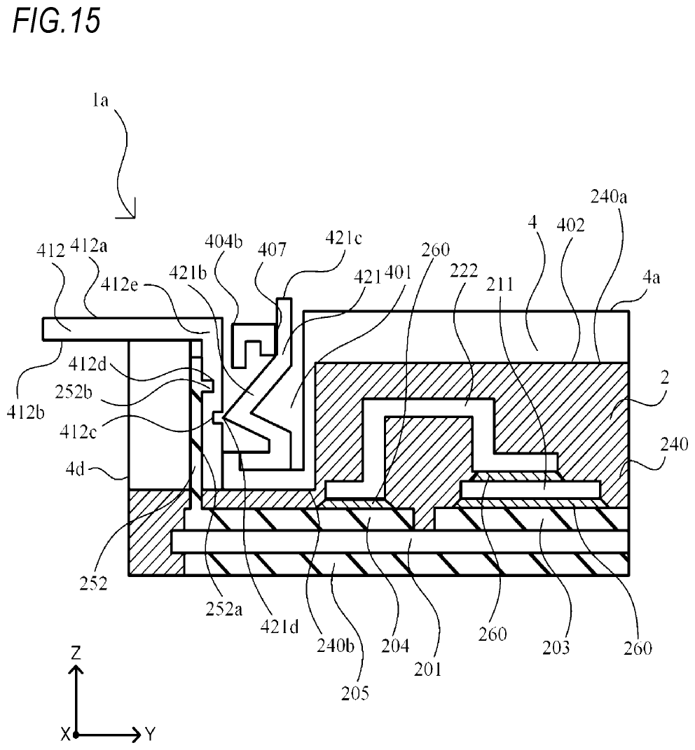

FIG. 14 shows a cross-sectional view of a main part illustrating Variation 2 of the semiconductor device 1a in the second embodiment. Note that the terminal contact portion 251 of the first conductor pattern 202 of the semiconductor package 2 and the external terminal 411, the terminal contact portion 253 of the second conductor pattern 203 of the semiconductor package 2 and the external terminal 413, the terminal contact portion 253 of the third conductor pattern 204 of the semiconductor package 2 and the external terminal 412, and the respective spring plates 421 have the same or similar configuration, arrangement, and dimension.

As shown in FIG. 14, the spring plate 421 of the semiconductor device 1a of Variation 2 has a first flexed portion 421b1 bent toward the terminal contact portion 252 side of the third conductor pattern 204 and a second flexed portion 421b2 bent toward the terminal contact portion 252 side of the third conductor pattern 204. The first flexed portion 421b1 is provided on the side surface 4d side of the case 4 with respect to the second flexed portion 421b2. Vertices 421d1 and 421d2 of the first flexed portion 421b1 and the second flexed portion 421b2 are provided facing the terminal contact portion 252 of the third conductor pattern 204.

The external terminal 412 is provided on the front surface 412a with a first fixing portion 412cl in contact with the vertex 421d of the first flexed portion 421b1 and a second fixing portion 412c2 in contact with the vertex 421d2 of the second flexed portion 421b2. The first fixing portion 412cl and the second fixing portion 412c2 each have a concave shape from the front surface 412a toward the rear surface 412b. The first fixing portion 412cl and the second fixing portion 412c2 each have a rectangular shape in a plan view, but are not particularly limited. In addition, widths (X direction) of the first fixing portion 412c1 and the second fixing portion 412c2 are equal to the width of the external terminal 412. The first fixing portion 412c1 and the second fixing portion 412c2 are provided without overlapping the groove portion 421d in a plan view.

When the external terminal 412 is inserted into the first insertion portion 404b of the case 4, the fixing portion 421c1 on the front surface 412a of the external terminal 412 and the first flexed portion 421b1 of the spring plate 421 come into contact with each other, and the fixing portion 421c2 and the second flexed portion 42162 of the spring plate 421 come into contact with each other. At that time, the first flexed portion 421b1 and the second flexed portion 421b2 of the spring plate 421 apply a pressing force to the external terminal 412 toward the contact terminal portion 252 side via the vertices 421d1 and 421d2. Therefore, the external terminal 412 and the terminal contact portion 252 are mechanically connected by the pressing force applied via the vertices 421d1 and 421d2. Additionally, a pressing force is applied to the external terminal 412 from a plurality of locations by a plurality of flexed portions (first flexed portion 421b1, second flexed portion 421b2) provided on the spring plate 421. Thereby, the mechanical connection between the external terminal 412 and the terminal contact portion 252 of the third conductor pattern 204 can be strengthened. Note that the arrangement, dimensions, and shapes of the first flexed portion 421b1 and the second flexed portion 421b2 can be changed appropriately. Additionally, as long as the first fixing portions 412c1 and 412c2 of the external terminal 412 are in contact with the vertices 421d1 and 421d2 of the spring plate 421, the arrangement and shapes thereof can be changed appropriately.

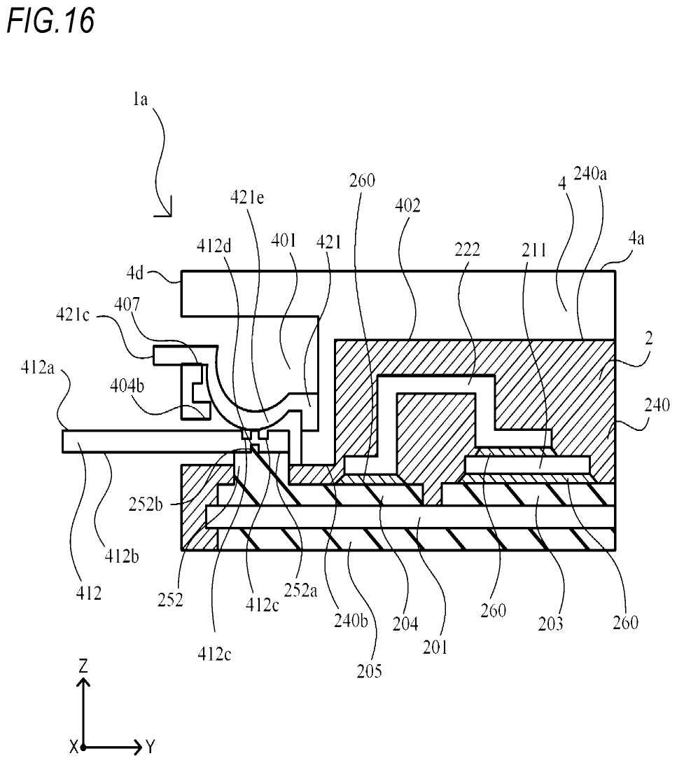

FIG. 15 shows a cross-sectional view of a main part illustrating Variation 3 of the semiconductor device 1a in the second embodiment.

As shown in FIG. 15, the first insertion portion 404b and the opening portion 407 of the case 4 of the semiconductor device 1a of Variation 3 are provided on the upper surface 4a of the case 4. The first insertion portion 404b is provided alongside the opening portion 407 on the side surface 4d side with respect to the opening portion 407. The tip end portion 421c of the spring plate 421 protrudes from the opening portion 407 on the upper surface 4a of the case 4 (+Z direction).

The terminal contact portion 252 of the third conductor pattern 204 is exposed upward (+Z direction) from the upper surface of the step portion 240b of the sealing body 240. In addition, the protrusion 252 of the terminal contact portion 252 has a pillar shape protruding from the surface 252a of the terminal contact portion 252 toward the spring plate 421 side (+X direction). Additionally, a surface of the terminal contact portion 252 opposite to the surface 252a is in contact with an inner wall portion of the spring plate accommodating portion 401 of the case 4.

The external terminal 412 has a bent portion 412e bent at a substantially right angle from a portion protruding from the first insertion portion 404b toward the side surface 4d side (−X direction) of the case 4. The external terminal 412 is bent at the bent portion 412e and extends along the upper surface 4a of the case 4.

When the external terminal 412 is inserted into the first insertion portion 404b of the case 4, the front surface 412a of the external terminal 412 and the vertex 421d of the flexed portion 421b of the spring plate 421 come into contact with each other, and the rear surface 412b and the surface 252a of the terminal contact portion 252 of the conductor pattern 204 come into contact with each other. At this time, the flexed portion 421b of the spring plate 421 applies a pressing force to the external terminal 412 toward the contact terminal portion 252 side via the vertex 421d. Therefore, the external terminal 412 and the terminal contact portion 252 are mechanically connected by the pressing force applied via the vertex 421d. In addition, when the external terminal 412 is attached to a capacitor or the like, a self-weight of the capacitor or the like is added to the external terminal 412 toward the cooler 3 side. That is, the external terminal 412 is pressed against the upper surface 4a of the case 4 by the self-weight of the capacitor or the like. Therefore, the holding force of the external terminal 412 can be increased.

Note that although detailed description is omitted, the terminal contact portions 251 and 253 of the first conductor pattern 202 of semiconductor package 2, the external terminals 411 and 413, and the first insertion portions 404a and 404c of the case 4 have the same or similar configuration, arrangement, and dimension as or to those of the terminal contact portion 252 of the third conductor pattern 204 of the semiconductor package 2, the external terminal 412, and the first insertion portion 404b of the case 4.

FIG. 16 shows a cross-sectional view of a main part illustrating Variation 4 of the semiconductor device 1a in the second embodiment.

As shown in FIG. 16, the spring plate 421 has a curved portion 421e curved so as to be bent toward the terminal contact portion 252 side of the third conductor pattern 204. The curved portion 421e has, for example, an R-shape. The curved portion 421e has a portion facing the terminal contact portion 252 of the third conductor pattern 204.

When the external terminal 412 is inserted into the first insertion portion 404b of the case 4, the front surface 412a of the external terminal 412 and the portion of the curved portion 421e of the spring plate 421 facing the terminal contact portion 252 come into contact with each other. In addition, the rear surface 412b comes into contact with the surface 252a of the terminal contact portion 252 of the conductor pattern 204. At this time, the curved portion 421e of the spring plate 421 applies a pressing force to the external terminal 412 toward the contact terminal portion 252 side. Therefore, the external terminal 412 and the terminal contact portion 252 are mechanically connected by the pressing force applied via the curved portion 421e.

Additionally, since the curved portion 421e is in surface contact with the front surface 412a, an area to which the pressing force is applied increases, and therefore, the mechanical connection between the external terminal 412 and the terminal contact portion 252 can be strengthened. Note that in FIG. 16, a plurality of fixing portions 412c of the external terminal 412 are provided, but the number is changed appropriately.

The embodiments of the semiconductor package and the semiconductor device according to the present invention are not limited to the above-described embodiments, and various changes, substitutions, and modifications can be made without departing from the spirit of the technical idea. Additionally, if the technical idea can be implemented in another method by development of the technology or another derived technology, the technology of the present invention may be implemented using such a method. Thus, the scope of the claims covers all embodiments that can be included within the scope of the technical idea.

1. A semiconductor module comprising:
a semiconductor element;
a conductor pattern including a terminal contact portion electrically connected to the semiconductor element;
a sealing body provided to seal the semiconductor element and including an upper surface from which the terminal contact portion is exposed;
a case provided with an accommodating portion configured to accommodate the sealing body; and
an elastic member that, when an external terminal is inserted, applies a pressing force from a surface of the inserted external terminal opposite to a surface in contact with the terminal contact portion,
wherein the case is provided with a first insertion portion into which the external terminal is inserted.

2. The semiconductor module according to claim 1, wherein the first insertion portion is provided on a side surface or an upper surface of the case.

3. The semiconductor module according to claim 1, wherein the elastic member is a spring plate.

4. The semiconductor module according to claim 3, wherein the spring plate includes a flexed portion bent toward the terminal contact portion side, and
wherein a vertex of the flexed portion is provided facing the terminal contact portion.

5. The semiconductor module according to claim 4, wherein the flexed portion of the spring plate is provided in plural.

6. The semiconductor module according to claim 4, wherein the case includes an opening portion,
wherein the spring plate includes a tip end portion protruding from the opening portion of the case, and
wherein the spring plate is not fixed to the case.

7. The semiconductor module according to claim 6, further comprising a protection member configured to cover the tip end portion of the spring plate,
wherein the protection member is attached to the opening portion.

8. The semiconductor module according to claim 6, wherein the first insertion portion and the opening portion are provided on an upper surface of the case.

9. The semiconductor module according to claim 3, wherein the spring plate includes a curved portion bent toward the terminal contact portion side, and
wherein the curved portion includes a portion facing the terminal contact portion.

10. The semiconductor module according to claim 2, wherein the case includes a second insertion portion into which a tool that separates the elastic member from the external terminal is inserted,
wherein the first insertion portion is provided on the terminal contact portion side with respect to the second insertion portion, and
wherein the second insertion portion penetrates from the side surface or upper surface of the case toward the elastic member.

11. A semiconductor module comprising:
a semiconductor element;
a conductor pattern including a terminal contact portion electrically connected to the semiconductor element;
a sealing body provided to seal the semiconductor element and including an upper surface from which the terminal contact portion is exposed;
a case provided with an accommodating portion configured to accommodate the sealing body; and
an elastic member that, when an external terminal is inserted, applies a pressing force from a surface of the inserted external terminal opposite to a surface in contact with the terminal contact portion; and
the external terminal sandwiched between the elastic member and the terminal contact portion and electrically connected to the terminal contact portion,
wherein the case is provided with a first insertion portion into which the external terminal is inserted.

12. The semiconductor device according to claim 11, wherein the external terminal includes a front surface in contact with the elastic member and a rear surface in contact with the terminal contact portion, and
wherein the front surface includes a fixing portion for fixing the elastic member at a position where the elastic member contacts.

13. The semiconductor device according to claim 12, wherein the fixing portion is a concave portion that is concave from the front surface toward the rear surface.

14. The semiconductor device according to claim 12, wherein the fixing portion is a plurality of convex portions protruding toward the elastic member side.

15. The semiconductor device according to claim 11, wherein the terminal contact portion includes a protrusion protruding toward the external terminal side, and
wherein the external terminal is provided with a groove portion into which the protrusion of the terminal contact portion is introduced.
